(19) United States
(12) Patent Application Publication
(10) Pub. No.: US 2025/0006882 A1
(43) Pub. Date: Jan. 2, 2025

(54) ELECTRONIC COMPONENT AND METHOD FOR PRODUCING AN ELECTRONIC COMPONENT

(71) Applicant: ams-OSRAM International GmbH, Regensburg (DE)

(72) Inventors: Thomas SCHWARZ, Regensburg (DE); Michael ZITZLSPERGER, Regensburg (DE)

(21) Appl. No.: 18/712,626

(22) PCT Filed: Nov. 22, 2022
(86) PCT No.: PCT/EP2022/082831

§ 371 Date: May 22, 2024

(30) Foreign Application Priority Data
Nov. 25, 2021 (DE) 10 2021 130 989.1

(51) Int. Cl. H01L 33/64; H01L 25/075

(52) U.S. Cl. CPC H01L 33/642; H01L 25/0753; H01L 33/647; H01L 2933/0075

(57) ABSTRACT

An electronic component has an electronic semiconductor chip and a heat sink which is provided for dissipating heat generated during the operation of the electronic semiconductor chip. A lower face of the electronic semiconductor chip is secured to an upper face of the heat sink and is thermally connected to the heat sink. A connecting surface which is formed between the lower face of the electronic semiconductor chip and the upper face of the heat sink is segmented into connecting surface segments, wherein adjacent connecting surface segments are mutually spaced on a plane which is parallel to the lower face of the electronic semiconductor chip.

The present invention relates to an electronic component and a method for producing an electronic component.

This patent application claims the priority of German patent application DE 10 2021 130 989.1, the disclosure content of which is hereby incorporated by reference.

The prior art discloses electronic components in which silicon chips are arranged on a heat sink composed of copper for heat dissipation purposes. One disadvantage is that silicon and copper comprise very different coefficients of thermal expansion. This causes thermomechanical stresses in the electronic component, as a result of which a reliability of the electronic component may be reduced. In order to counteract that, it is known to arrange an elastic adhesive between a silicon chip and the heat sink composed of copper. However, this entails the disadvantage that a thermal conductivity from the electronic semiconductor chip to the heat sink is reduced.

An object of the present invention is to provide an improved electronic component and to specify a method for producing the electronic component. This object is achieved by an electronic component and a method for producing an electronic component comprising the features of the respective independent claims. Advantageous developments are specified in dependent claims.

An electronic component comprises an electronic semiconductor chip and a heat sink provided for dissipating heat generated during the operation of the electronic semiconductor chip. The electronic semiconductor chip is secured by an underside on a top side of the heat sink and is thermally connected to the heat sink. A connecting surface formed between the underside of the electronic semiconductor chip and the top side of the heat sink is segmented into connecting surface segments. Adjacent connecting surface segments are formed spaced apart from one another in a plane parallel to the underside of the electronic semiconductor chip.

The electronic semiconductor chip and the heat sink may comprise different coefficients of thermal expansion. This causes a thermomechanical stress in the electronic component. By virtue of the fact that the connecting surface between the underside of the electronic semiconductor chip and the top side of the heat sink is segmented into connecting surface segments spaced apart from one another, the thermomechanical stress is reduced since a thermomechanical stress may occur only in the region of the connecting surface elements, and not in the region of the entire underside of the electronic component or of the entire top side of the heat sink. Advantageously, a more reliable and more efficient electronic component may be provided as a result.

It is furthermore advantageously not necessary to use an elastic adhesive for securing the electronic semiconductor chip on the top side of the heat sink in order to reduce thermomechanical stresses. Instead, a more thermally conductive solder material may be used in order to secure the electronic semiconductor chip on the top side of the heat sink. The electronic semiconductor chip may be cooled particularly efficiently in this way, whereby an output power of the electronic semiconductor chip may be increased.

In one embodiment, the heat sink is segmented laterally into heat-conducting segments. Adjacent heat-conducting segments are spaced apart in a plane parallel to the top side of the heat sink by way of first trenches. The first trenches extend from an underside of the heat sink as far as the top side of the heat sink. In this embodiment, the connecting surface is segmented by virtue of the heat sink itself being laterally segmented. In this case, the connecting surface segments are formed in regions of the heat-conducting segments of the heat sink.

In one embodiment, the heat-conducting segments are embedded into an elastic mold material. However, the heat-conducting segments may also be embedded into a hard carrier. By comparison with a hard carrier, however, the elastic mold material, owing to its elasticity, affords the advantage that thermomechanical stresses are reduced. Embedding the heat-conducting segments into a hard carrier affords the advantage of simpler handling when producing the electronic component. The heat-conducting segments may also be arranged together with the elastic mold material in a cutout of a carrier and be embedded into the elastic mold material.

In one embodiment, the electronic semiconductor chip is segmented laterally into chip segments at least in a region adjoining its underside. Adjacent chip segments are spaced apart in a plane parallel to the underside of the electronic semiconductor chip by way of second trenches. In this embodiment, the connecting surface is segmented by virtue of the electronic semiconductor chip being laterally segmented. In this case, the connecting surface segments are formed in regions of the chip segments of the electronic semiconductor chip.

In one embodiment, the electronic semiconductor chip comprises a substrate. The substrate is secured by an underside on the top side of the heat sink and is thermally connected to the heat sink. The substrate is segmented laterally into substrate segments constituting the chip segments at least in a region adjoining its underside. Adjacent substrate segments are spaced apart in a plane parallel to the underside of the electronic semiconductor chip by way of the second trenches. The substrate segments are connected to one another via a membrane formed at a top side of the substrate and in the region of the second trenches. Advantageously, thermomechanical stresses in regions of the connecting surfaces are reduced as a result. This is caused by the substrate segments being connected to one another via the membrane. The membrane is formed in flexible fashion and is provided for absorbing at least some of the thermomechanical stresses that occur, a deformation of the membrane being caused. For this reason, components of the electronic semiconductor chip that are arranged on a top side of the substrate and in the region of the membrane should be provided for noncritical functions of the electronic semiconductor chip. The components provided for the noncritical functions may be electrical conductor tracks, for example.

In one embodiment, the substrate segments are formed in a manner tapering toward the heat sink. To put it another way, the second trenches are formed in a manner tapering toward the top side of the substrate. An area of the substrate that is taken up by the membrane is reduced as a result. It is possible as a result to arrange more components on the top side of the substrate and in regions outside the membrane, the functions of which are advantageously not impaired by a deformation of the membrane.

In one embodiment, the heat-conducting segments are arranged on a top side of a ceramic substrate. In this variant, the electronic semiconductor chip is arranged on a so-called DBC (direct bonded copper) carrier. A DBC carrier typically comprises the ceramic substrate and two heat sinks arranged respectively at the top side and an underside of the ceramic substrate. Production is carried out using a bonding method. In this variant, the heat-conducting segments may be produced for example by etching the heat sink arranged on the top side of the ceramic substrate.

In one embodiment, the ceramic substrate is secured by an underside, located opposite the top side of the ceramic substrate, on a top side of a further heat sink. The further heat sink is segmented laterally into further heat-conducting segments. Adjacent further heat-conducting segments are spaced apart in a plane parallel to the top side of the further heat sink by way of third trenches. The third trenches extend from an underside of the further heat sink as far as the top side of the further heat sink. By virtue of the further heat sink also being formed in a segmented manner, thermomechanical stresses are advantageously additionally reduced.

In one embodiment, an aspect ratio between a thickness of the heat-conducting segments and a lateral extent of the heat-conducting segments is less than one. Advantageously, the electronic component comprises a particularly flat design as a result.

A method for producing an electronic component comprises following method steps: An electronic semiconductor chip is provided. Furthermore, a heat sink provided for dissipating heat generated during the operation of the electronic semiconductor chip is provided. The heat sink and/or the electronic semiconductor chip segmented are/is provided in a segmented manner. The heat sink is provided in a manner segmented laterally into heat-conducting segments and/or the electronic semiconductor chip is provided in a manner segmented laterally into chip segments at least in a region adjoining its underside. Adjacent heat-conducting segments are spaced apart in a plane parallel to the top side of the heat sink by way of first trenches extending from an underside of the heat sink as far as the top side of the heat sink and/or adjacent chip segments are spaced apart in a plane parallel to the underside of the electronic semiconductor chip by way of second trenches. The electronic semiconductor chip is arranged on the heat sink. The electronic semiconductor chip is secured by an underside on a top side of the heat sink and is thermally connected to the heat sink.

In one embodiment, the heat-conducting segments are embedded into an elastic mold material.

In one embodiment, providing the heat sink comprises the following method steps: Thermally conductive bodies are provided. Heat-conducting segments of the heat sink are produced by grinding or pressing the thermally conductive bodies. Alternatively, the heat-conducting segments may also be produced by etching a leadframe.

In one embodiment, the electronic semiconductor chip comprises a substrate. The substrate is secured by an underside on the top side of the heat sink and is thermally connected to the heat sink. The substrate is segmented laterally into substrate segments constituting the chip segments at least in a region adjoining its underside, in such a way that the substrate segments are spaced apart in a plane parallel to the underside of the electronic semiconductor chip by way of the second trenches and the substrate segments are connected to one another via a membrane formed at a top side of the substrate and in the region of the second trenches.

The above-described properties, features and advantages of this invention and the way in which they are achieved will become clearer and more clearly understood in association with the following description of the exemplary embodiments which are explained in greater detail in association with the drawings, in which:

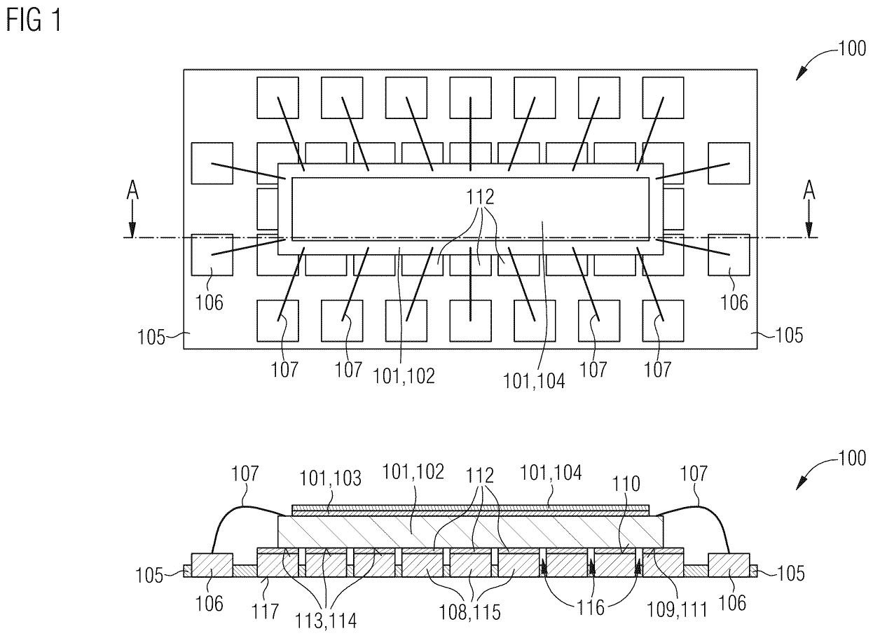

FIG. 1: shows an electronic component in accordance with a first embodiment in a plan view and a cross-sectional view;

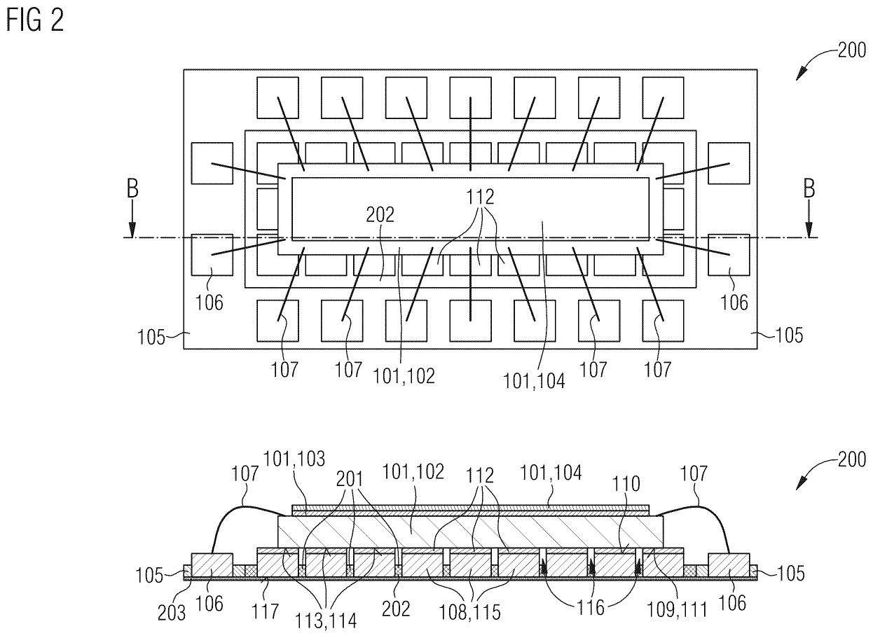

FIG. 2: shows an electronic component in accordance with a second embodiment in a plan view and a cross-sectional view;

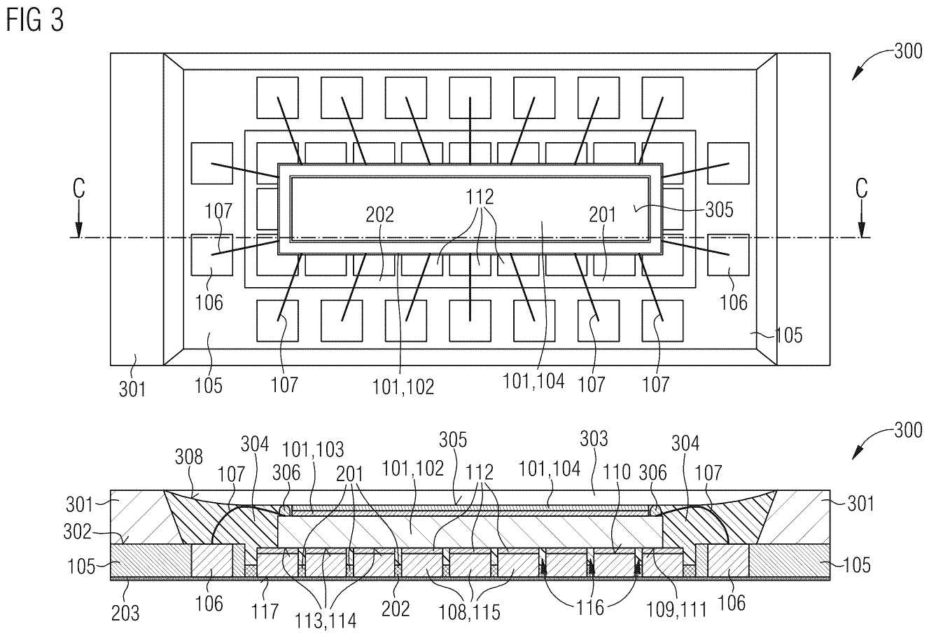

FIG. 3: shows an electronic component in accordance with a third embodiment in a plan view and a cross-sectional view;

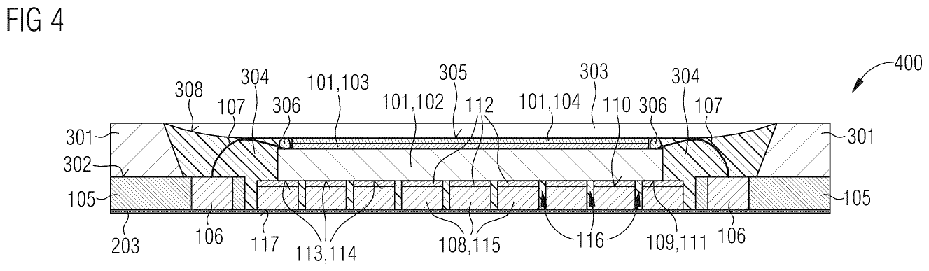

FIG. 4: shows an electronic component in accordance with a fourth embodiment in a cross-sectional view;

FIG. 5: shows an electronic component in accordance with a fifth embodiment in a cross-sectional view;

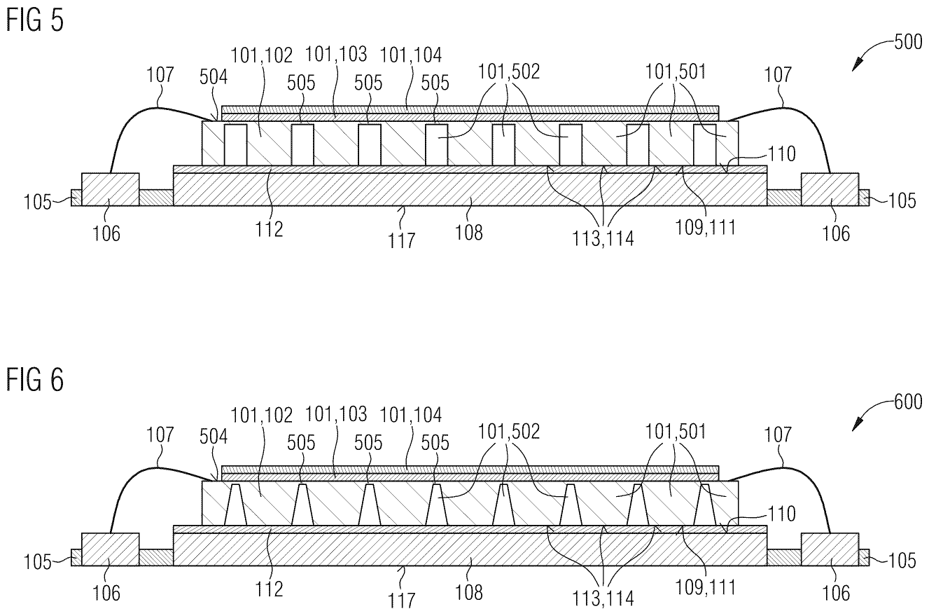

FIG. 6: shows an electronic component in accordance with a sixth embodiment in a cross-sectional view;

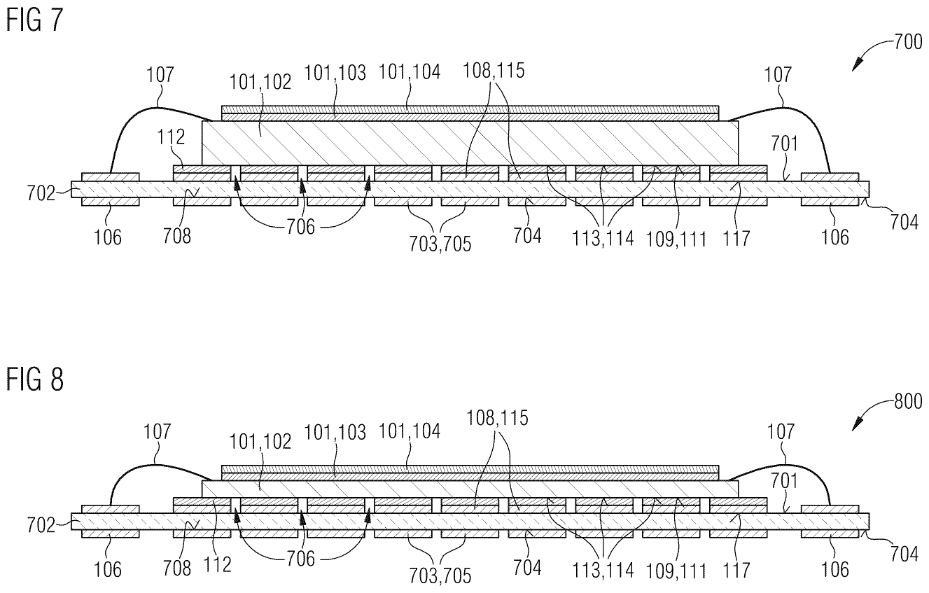

FIG. 7: shows an electronic component in accordance with a seventh embodiment in a cross-sectional view;

FIG. 8: shows an electronic component in accordance with an eighth embodiment in a cross-sectional view;

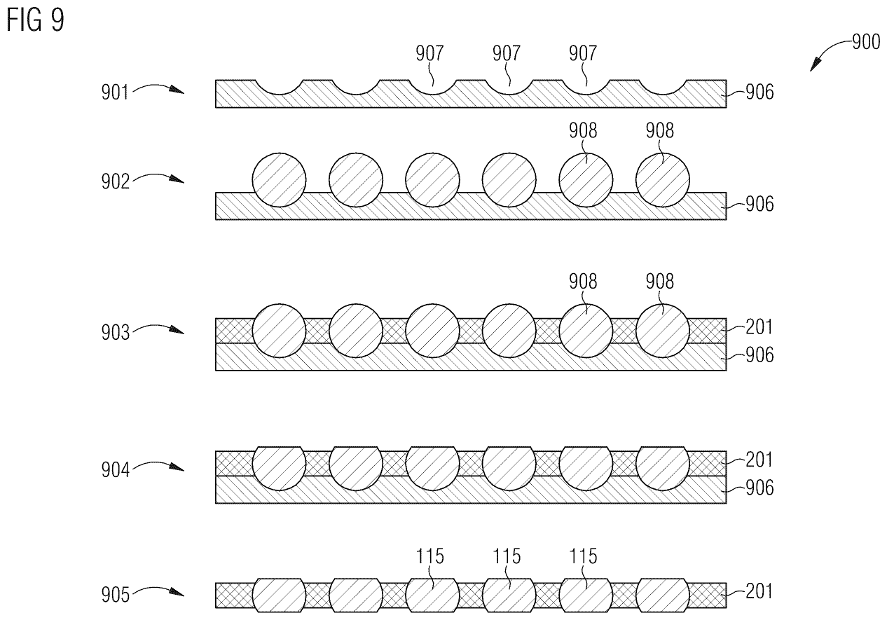

FIG. 9: shows method steps of a first exemplary embodiment for producing heat-conducting segments of a heat sink of an electronic component;

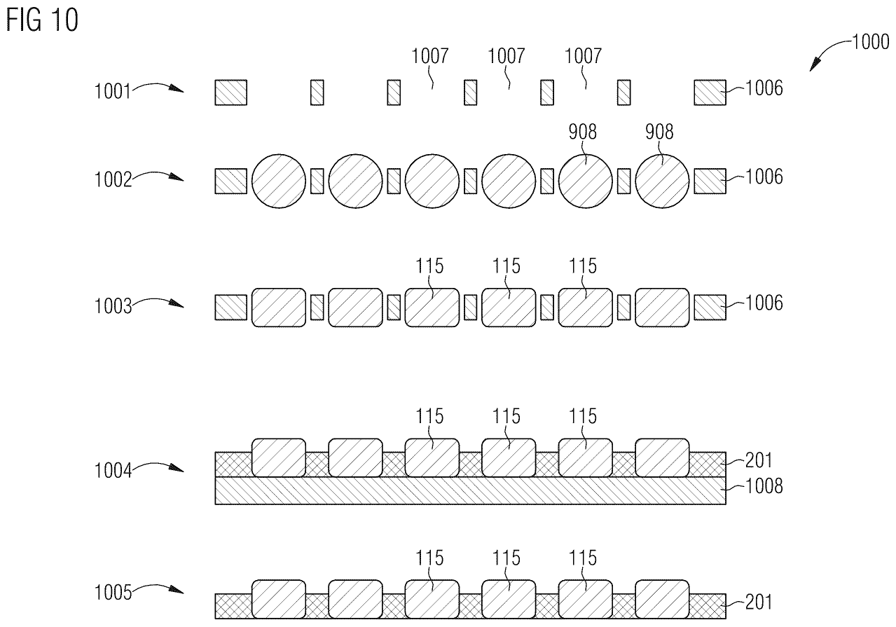

FIG. 10: shows method steps of a second exemplary embodiment for producing the heat-conducting segments of the heat sink;

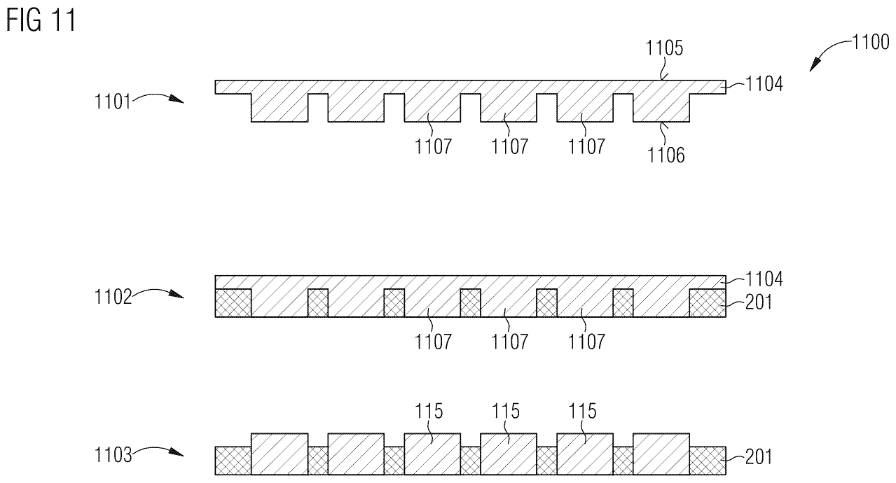

FIG. 11: shows method steps of a third exemplary embodiment for producing the heat-conducting segments of the heat sink; and

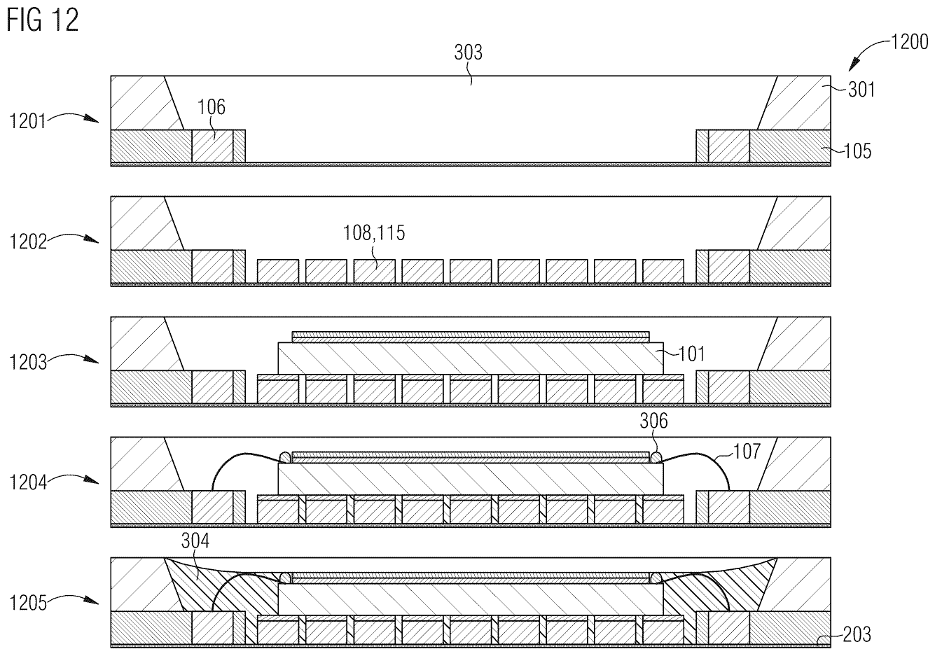

FIG. 12: shows method steps for producing the electronic component in accordance with the fourth embodiment.

FIG. 1 schematically shows an electronic component 100 in accordance with a first embodiment in a plan view and in a cross-sectional view along a plane A-A, indicated by a dashed line in the plan view.

The electronic component 100 comprises an electronic semiconductor chip 101. The electronic semiconductor chip 101 comprises a substrate 102 and at least one electronic semiconductor arrangement 103 arranged on the substrate 102. The substrate 102 comprises silicon by way of example. However, the substrate 102 may comprise a different material, for example a different semiconductor. However, the substrate 102 may also be dispensed with. In this case, the electronic semiconductor chip 101 is formed as a substrateless semiconductor chip 101.

By way of example, the electronic semiconductor arrangement 103 comprises a plurality of light-emitting diodes formed for emitting electromagnetic radiation, although it may be expedient for the electronic semiconductor arrangement 103 to comprise just one light-emitting diode. The light-emitting diodes are not illustrated in FIG. 1, for the sake of simplicity. In this case, the electronic semiconductor arrangement 103 may be referred to as optoelectronic semiconductor arrangement 103 and the electronic component 100 may be referred to as optoelectronic component 100. The optoelectronic component 100 may for example be part of a projection means or part of an automotive headlight.

By way of example, the optoelectronic semiconductor arrangement 103 comprises a conversion layer 104 arranged over the optoelectronic semiconductor arrangement 103. The conversion layer 104 is provided for converting a wavelength of electromagnetic radiation emitted by the light-emitting diodes. The optoelectronic semiconductor arrangement 103 may also comprise a plurality of conversion layers, each provided for one light-emitting diode. For conversion purposes, the conversion layer 104 comprises a conversion material provided for absorbing electromagnetic radiation comprising a first wavelength, and for re-emitting electromagnetic radiation comprising a second wavelength, thereby causing the wavelength to be converted. The conversion material of the conversion layer 104 is embedded into a silicone layer by way of example, but that is not absolutely necessary. Instead, the conversion material may itself be arranged in the form of a layer over the optoelectronic semiconductor arrangement 103. However, the conversion layer 104 may also be dispensed with.

The electronic semiconductor arrangement 103 may alternatively or additionally comprise for example at least one MOSFET (metal oxide semiconductor field-effect transistor). The electronic semiconductor arrangement 103 may alternatively or additionally also comprise at least one insulated-gate bipolar transistor (IGBT). In other words, the electronic component 100 need not necessarily be formed as an optoelectronic component 100. For example, the electronic component 100 may be formed as a power module. The electronic semiconductor arrangement 103 may alternatively or additionally also comprise electronic and/or optoelectronic components other than those mentioned. The electronic semiconductor chip 101 may comprise for example an edge length of more than 5 mm. However, the electronic semiconductor chip 101 may also comprise a different edge length.

The electronic component 100 furthermore comprises a carrier substrate 105. The carrier substrate 105 may be formed for example as a printed circuit board (PCB). Alternatively, the carrier substrate 105 may also be formed as a QFN (quad flat no leads) substrate. In this case, the carrier substrate 105 comprises for example a plastic, for instance an epoxy resin. However, the carrier substrate 105 may comprise a different material.

Electrical contacts 106 are embedded into the carrier substrate 105. By way of example, the electrical contacts 106 comprise a thickness that is greater than a thickness of the carrier substrate 105. This is not absolutely necessary, however. The thickness of the electrical contacts 106 and the thickness of the carrier substrate 105 may also be equal in magnitude, for example. The electrical contacts 106 comprise copper by way of example, but they may also comprise some other electrically conductive material. Components of the electronic semiconductor arrangement 103, in order to be supplied with electrical energy, are connected to the electrical contacts 106 via bond wires 107. Merely by way of example, FIG. 1 shows that the electronic semiconductor arrangement 106 is connected to a total of eighteen electrical contacts 106. A number of the electrical contacts 106 and of the bond wires 107 depends on the type and a number of the components of the electronic semiconductor arrangement 103.

Heat is generated during the operation of the electronic semiconductor chip 101. By way of example, a thermal load of greater than 1 W may be caused during operation, the thermal load not being restricted to the specified range. In order to dissipate heat generated during the operation of the electronic semiconductor chip 101, the electronic component 100 comprises a heat sink 108. The electronic semiconductor chip 101 is secured by an underside 109 on a top side 110 of the heat sink 108 and is thermally connected to the heat sink 108. In the illustrated example of the electronic semiconductor chip 101 comprising substrate 102, an underside 111 of the substrate 102 constitutes the underside 109 of the electronic semiconductor chip 101. The heat sink 108 comprises copper by way of example. However, the heat sink 108 may also comprise some other thermally conductive material.

By way of example, a solder material 112 is arranged between the underside 109 of the electronic semiconductor chip 101 and the top side 110 of the heat sink 108. The solder material 112 comprises a gold-tin alloy by way of example. However, the solder material 112 may alternatively comprise a tin-copper alloy, for example. The solder material 112 is provided for securing the electronic semiconductor chip 101 on the heat sink 108. The solder material 112 may also be dispensed with. Alternatively, the electronic semiconductor chip 101 may be secured for example by way of an adhesive arranged between the underside 109 of the electronic semiconductor chip 103 and the top side 110 of the heat sink 108. However, the solder material 112 affords the advantage that it comprises a particularly high thermal conductivity.

When producing the electronic component 100, the solder material 112 may for example firstly be arranged on the underside 109 of the electronic semiconductor chip 103 or on the underside 111 of the substrate 102. The electronic semiconductor chip 101 or the substrate 102 is preheated, wherein the electronic semiconductor chip 101 or the substrate 102 is preheated for example to a temperature of 200° C. This temperature specification merely constitutes an exemplary specification. The electronic semiconductor chip 101 or the substrate 102 may also be preheated to a different temperature. The electronic semiconductor chip 103 is supplied on a hot mounting tool, which for example, but not necessarily, comprises a temperature of 350° C., and is pressed onto the heat sink 108. When the hot mounting tool is removed, the solder material 112 solidifies.

A connecting surface 113 formed between the underside 109 of the electronic semiconductor chip 103 and the top side 110 of the heat sink 108 is segmented into connecting surface segments 114. Adjacent connecting surface segments 114 are formed spaced apart from one another in a plane parallel to the underside 109 of the electronic semiconductor chip 103. In the case of the electronic component 100 in accordance with the first embodiment, the connecting surface 114 is laterally segmented by virtue of the heat sink 108 being segmented laterally into heat-conducting segments 115. By way of example, the heat sink 108 comprises twenty-seven heat-conducting segments 115. However, the number of heat-conducting segments 115 may also be smaller or larger. The heat-conducting segments 115 are at a distance from one another of a few μm, for example, which distance may also be smaller or larger, however.

Adjacent heat-conducting segments 115 are spaced apart in a plane parallel to the top side 110 of the heat sink 108 by way of first trenches 116. The first trenches 116 extend from an underside 117 of the heat sink as far as the top side 110 of the heat sink 108. Merely by way of example, the heat-conducting segments 115 or the heat sink 108 comprise(s) a thickness that is greater than the thickness of the carrier substrate 105. This is not necessary, however; the heat sink 108 or the heat-conducting segments 115 and the carrier substrate 105 may also comprise identical thicknesses, for example. However, the heat sink 108 or the heat-conducting segments 115 may also be thinner than the carrier substrate 105. By way of example, an aspect ratio between the thickness of the heat-conducting segments 115 and a lateral extent of the heat-conducting segments 115 is less than one, but that is not necessarily required. Such an aspect ratio affords the advantage, however, that the electronic component 100 is formed in particularly flat fashion. The heat-conducting segments 115 may comprise a thickness of 200 μm, for example. However, this is merely an exemplary specification of a value. The heat-conducting segments 115 may also comprise a different thickness.

The heat sink 108 or the heat-conducting segments 115 is or are embedded into the carrier substrate 105. If the carrier substrate 105 is a printed circuit board, then the heat-conducting segments 115 may be formed in the form of so-called PCB inlays. PCB inlays may be produced for example by a material that constitutes the heat-conducting segments 115 being pressed into through openings in the printed circuit board. The electrical contacts 106 may likewise be formed as PCB inlays.

If the carrier substrate 105 is a QFN substrate, the heat-conducting segments 115 may be embedded into the carrier substrate 105 for example by way of a molding method, for example by way of film-assisted transfer molding. During film-assisted transfer molding, a mold tool encloses a cavity, with a film being arranged on an inner wall of the cavity. The heat-conducting segments 115 are arranged in the cavity. The cavity is filled with a mold material, for example an epoxy resin, and the mold material is cured, whereby the heat-conducting segments 115 are embedded into the material of the carrier substrate 105. In this case, the heat-conducting segments 115 are embedded together with the electronic contacts 106 into the carrier substrate 105.

Another possibility for embedding the heat-conducting segments 115 into the carrier substrate 105 consists in producing through openings in the carrier substrate 105, which are subsequently filled by way of electrodeposition of the material of the heat sink 108, whereby the heat-conducting segments 115 are produced and at the same time are arranged in the through openings or are embedded into the carrier substrate 105. Through openings in the carrier substrate 105 may be produced using a laser or by way of mechanical drilling, for example.

Since the electronic semiconductor chip 103 or the substrate 102 and the heat sink 108 comprise different coefficients of thermal expansion, thermomechanical stresses may be caused during the operation of the electronic semiconductor chip 103 and may adversely affect a performance of the electronic component 100. This is the case in particular if the substrate 102 comprises silicon and the heat sink 108 comprises copper, since silicon and copper comprise particularly different coefficients of thermal expansion. By virtue of the connecting surface 113 between the electronic semiconductor chip 103 and the heat sink 108 being segmented, thermomechanical stresses in the electronic component 100 may be reduced. Thermomechanical stresses essentially occur only in the region of the connecting surface segments 114 or in the region of the heat-conducting segments 115 of the heat sink 108. To put it another way, a manifestation of a bimetal effect in regions between the connecting surface segments 114 or between the heat-conducting segments 115 is interrupted, whereby thermomechanical stresses are reduced overall.

FIG. 2 schematically shows an electronic component 200 in accordance with a second embodiment in a plan view and in a cross-sectional view along a plane B-B, indicated by a dashed line in the plan view. The electronic component 200 in accordance with the second embodiment comprises great similarities with the electronic component 100 in accordance with the first embodiment. Similar or identical elements are provided with the same reference signs for this reason. Only differences with respect to the electronic component 100 in accordance with the first embodiment are explained in the following description.

In contrast to the electronic component 100 in accordance with the first embodiment, the heat sink 108 or the heat-conducting segments 115 of the heat sink 105 is or are embedded into an elastic mold material 201. The elastic mold material 201 comprises a silicone by way of example. However, the elastic mold material 201 may comprise a different elastic material. The elastic mold material 201 comprises for example a modulus of elasticity of less than 100 MPa. This value range is merely by way of example, however, and so the elastic mold material 201 may also comprise a different modulus of elasticity. The elastic mold material 201 is arranged together with the heat sink 108 or the heat-conducting segments 115 in a cutout 202 of the carrier substrate 105.

In the context of producing the electronic component 200, firstly the heat-conducting segments 115 are embedded into the elastic mold material 201. Afterward, the heat-conducting segments 115 embedded into the elastic mold material 201 are embedded with the elastic mold material 201 into the carrier substrate 105, for example by way of film-assisted transfer molding. The elastic mold material 201 constitutes an elastic mat arranged in the cutout 202 of the carrier substrate 105.

For a stability of the electronic component 200 in accordance with the second embodiment, the latter additionally comprises an adhesive tape 203. The adhesive tape 203 is arranged on an underside 204 of the carrier substrate 105 facing away from the electronic semiconductor chip 101, on an underside 205 of the elastic material 201 facing away from the electronic semiconductor chip 101, and on the underside 117 of the heat sink 108 or on undersides 117 of the heat-conducting segments 115, and is provided for holding together the carrier substrate 105, the heat-conducting segments 115 and the elastic material 201. The adhesive tape 203 may be removed after production of the electronic component 200.

In an alternative production method, firstly the carrier substrate 105 with the electrical contacts 106 and the cutout 202 is provided and arranged on the adhesive tape 203. The heat-conducting segments 115 are then arranged on the adhesive tape 203 and in the cutout 202. The elastic material 201 is poured into interspaces between the heat-conducting segments 115 that constitute the first trenches 116, and is cured.

Merely by way of example, FIG. 2 shows that the elastic mat and the carrier substrate 105 comprise identical thicknesses, wherein the heat-conducting segments 115 likewise by way of example comprise a greater thickness than the carrier substrate 105 and the elastic mold material 201 or the elastic mat. However, each of the thicknesses of the carrier substrate 105, the elastic mold material 201 and the heat-conducting segments 115 may also be chosen to be smaller or larger than is shown in FIG. 2; for example, the thickness of the heat-conducting segments 115 may correspond to the thickness of the carrier substrate 105 and/or of the elastic mold material 201.

By comparison with a harder carrier substrate 105, such as a printed circuit board or a QFN substrate, for instance, the elastic mold material 201 into which the heat-conducting segments 115 are embedded affords the advantage that mechanical stresses in regions between the heat-conducting segments 115 may additionally be reduced since the elastic mold material 201, owing to its elasticity, experiences a deformation in the case of thermomechanical stresses in the region of the heat-conducting segments 115.

FIG. 3 schematically shows an electronic component 300 in accordance with a third embodiment in a plan view and in a cross-sectional view along a plane C-C, indicated by a dashed line in the plan view. The electronic component 300 in accordance with the third embodiment comprises great similarities with the electronic component 200 in accordance with the second embodiment. Similar or identical elements are provided with the same reference signs for this reason. Only differences with respect to the electronic component 200 in accordance with the second embodiment are explained in the following description.

The electronic component 300 comprises a frame 301 arranged on the carrier substrate 105. The frame 301 is arranged on a top side 302 of the carrier substrate 105 and laterally bounds the cutout 202 of the carrier substrate 105. The frame 301 thus also laterally bounds the elastic mold material 201 arranged in the cutout 202 and the heat-conducting segments 115 embedded into the elastic mold material 201. The frame 301 comprises an epoxy resin by way of example. However, the frame 301 may comprise a plastic. In the context of producing the electronic component 300, the frame 301 may be arranged on the top side 302 of the carrier substrate 105 by way of film-assisted transfer molding, for example.

The carrier substrate 105, the elastic mold material 201 arranged in the cutout 202 of the carrier substrate 105 and the heat-conducting segments 115 embedded into the mold material 201, and the frame 301 enclose a cavity 303. The electronic semiconductor chip 101 is arranged in the cavity 303. In addition, a further mold material 304 is arranged in the cavity. The further mold material 304 comprises a silicone by way of example. However, the further mold material 304 may comprise some other plastic. The further mold material 304 and the elastic mold material 201 may comprise different materials or identical materials. For example, the elastic mold material 201 and the further mold material 304 may comprise the same silicone. The electronic semiconductor chip 101 and the bond wires 107 are embedded into the further mold material 304. The electronic semiconductor chip 101 and the bond wires 107 are protected as a result. By way of example, the further mold material 304 is partly arranged in the cutout of the carrier substrate 105. As a result, the heat-conducting segments 115 are embedded partly into the elastic mold material 201 and partly into the further mold material 304.

The further mold material 304 may be arranged in the cavity of the electronic component 300 by way of a metering method, for example. In order that a top side 305 of the electronic semiconductor chip 101 facing away from the heat sink 108 is not covered by the further mold material 304, the electronic semiconductor chip 101 comprises a dam 306. The dam comprises a plastic, for example a silicone. The dam 306 is arranged on the top side 305 of the electronic semiconductor chip 101 and bounds the electronic semiconductor arrangement 103. In the illustrated example in FIG. 3 of the electronic component 300 comprising substrate 102, the dam 306 is arranged on a top side 307 of the substrate 102. The dam 306 is provided as a barrier against the further mold material 304 arranged in the cavity 303. The cavity 303 is filled with the further mold material 304 as far as the dam 306, a potting surface 308 thereby being formed in the region of the dam 306.

FIG. 4 schematically shows an electronic component 400 in accordance with a fourth embodiment in a plan view and in a cross-sectional view along a plane D-D, indicated by a dashed line in the plan view. The electronic component 400 in accordance with the fourth embodiment comprises great similarities with the electronic component 300 in accordance with the third embodiment. Similar or identical elements are provided with the same reference signs for this reason. Only differences with respect to the electronic component 300 in accordance with the third embodiment are explained in the following description.

In comparison with the electronic component 300 in accordance with the third embodiment, the electronic component 400 in accordance with the fourth embodiment comprises only the further mold material 304. By contrast, the elastic mold material 201 in the form of the elastic mat is not part of the electronic component 400 in accordance with the fourth embodiment. The further mold material 304 is arranged in the cavity 303 and in the cutout 202 of the carrier substrate 105. The cutout 202 of the carrier substrate 105 is completely filled by the further mold material 304. The heat sink 108 or the heat-conducting segments 115 is or are completely embedded into the further mold material 304 in this case. The further mold material 304 is formed in elastic fashion. In this embodiment, too, the adhesive tape 203 may be dispensed with, since the further mold material 304 may impart a sufficient stability to the electronic component 400. The adhesive tape 203 may be removed after production of the electronic component 200. It merely serves to fix the heat-conducting segments 115 as long as the further mold material 304 does not yet hold together the heat-conducting segments 115 and the carrier substrate 105 or the electronic component 400.

In a further embodiment of the electronic component, not illustrated in the figures, the heat-conducting segments 115 of the heat sink 108 are embedded into the carrier substrate 105 in accordance with the embodiment in FIG. 1. The frame 301 is arranged on the carrier substrate 105 in accordance with the variant in FIG. 2 and the further mold material 304 is arranged in the cavity. Depending on the ratio of the thickness of the heat sink 108 or of the heat-conducting segments 115 to the thickness of the carrier substrate 105, it may be the case that the heat-conducting segments 115 are at least partly embedded into the further mold material 304.

FIG. 5 schematically shows an electronic component 500 in accordance with a fifth embodiment in a cross-sectional view. The electronic component 500 in accordance with the fifth embodiment comprises great similarities with the electronic component 100 in accordance with the first embodiment. Similar or identical elements are provided with the same reference signs for this reason. Only differences with respect to the electronic component 100 in accordance with the first embodiment are explained in the following description.

In the case, too, of the electronic component 500 in accordance with the fifth embodiment, the connecting surface 113 formed between the underside 109 of the electronic semiconductor chip 101 and the top side 110 of the heat sink 108 is segmented into connecting surface segments 114. Adjacent connecting surface segments 114 are formed spaced apart from one another in a plane parallel to the underside 109 of the electronic semiconductor chip 101. However, the connecting surface 113 is not segmented by virtue of the heat sink 108 being segmented. Instead, the electronic semiconductor chip 101 is segmented laterally into chip segments 501 at least in a region adjoining its underside 109. Adjacent chip segments 501 are spaced apart in a plane parallel to the underside 109 of the electronic semiconductor chip 301 by way of second trenches 502.

In the exemplary illustration in FIG. 5, the electronic semiconductor chip 101 comprises the substrate 102. In this case, it is expedient for the substrate 102 to be formed in a segmented manner. In the case of a substrateless electronic semiconductor chip 101, too, it is possible, however, for chip segments 501 to be formed at the underside 109 of the electronic semiconductor chip 101 facing the heat sink 108.

In the illustrated example in FIG. 5, the substrate 102 is secured by its underside 111 on the top side 110 of the heat sink 108 and is thermally connected to the heat sink 108. Merely by way of example, the solder material 12 in FIG. 5 is arranged areally on the heat sink 108. However, the solder material 112 may also be arranged only in regions of the substrate segments 503 or of the chip segments 501.

The substrate 102 is segmented laterally into substrate segments 503 constituting the chip segments 501 at least in a region adjoining its underside 111. Adjacent chip segments 503 are spaced apart in a plane parallel to the underside 109 of the electronic semiconductor chip 101 by way of the second trenches 502. The second trenches 502 may be produced by photolithography, for example, wherein the substrate 102 is etched at its underside 111.

The substrate segments 503 are connected to one another via a membrane 505 formed at a top side 504 of the substrate 102 and in the region of the second trenches 502. The membrane 505, by virtue of its small thickness, is formed in flexible fashion and provided for absorbing at least some of the thermomechanical stresses that occur, which may occur on account of different coefficients of thermal expansion of the substrate 102 and the heat sink 108. Thermomechanical stresses in the electronic component 500 are reduced as a result. The membrane 505 comprises a thickness of 5 μm, for example. However, the membrane 505 may also comprise a different thickness. A flexibility of the membrane 505 depends on its thickness and may be influenced in this way.

In other embodiments, the heat sink 108 is segmented into heat-conducting segments 115 and the electronic semiconductor chip 101 is also segmented into chip segments 501 or, in the case of an electronic semiconductor chip 101 comprising a substrate 102, the substrate 102 is segmented into substrate segments 503. Consequently, the electronic components 100, 200, 300, 400 in accordance with the first, second, third and fourth embodiments may also comprise, in addition to the segmented heat sink 108, a segmented electronic semiconductor chip 101 comprising chip segments 501 or substrate segments 503. In this case, a respective substrate segment 505 is respectively arranged on a heat-conducting segment 115. As a result, thermomechanical stresses may occur only in the region of the connecting surface segments 114. Thermomechanical stresses present may be further reduced by the membrane 505. In addition, the heat-conducting segments 115 may be embedded into the elastic mold material 201 and/or an elastic further mold material 304, which affords the advantage over a hard carrier substrate 105 that thermomechanical stresses may be reduced.

FIG. 6 schematically shows an electronic component 600 in accordance with a sixth embodiment in a cross-sectional view. The electronic component 600 in accordance with the sixth embodiment comprises great similarities with the electronic component 500 in accordance with the fifth embodiment. Similar or identical elements are provided with the same reference signs for this reason. Only differences with respect to the electronic component 500 in accordance with the fifth embodiment are explained in the following description.

In contrast to the electronic component 500 in accordance with the fifth embodiment, the substrate segments 503 of the electronic component 600 in accordance with the sixth embodiment are formed in a manner tapering toward the heat sink 108. To put it another way, the second trenches 502 are formed in a manner tapering toward the membrane 505. As a result, in comparison with the electronic component 500 in accordance with the fifth embodiment, the membrane 505 is constituted by a smaller part of the top side 504 of the substrate 102. A larger mounting area for electronic semiconductor arrangements 103 is thus available.

The electronic components 100, 200, 300, 400 in accordance with the first, second, third and fourth embodiments may also comprise, in addition to the segmented heat sink 108, a segmented electronic semiconductor chip 101 comprising substrate segments 503 formed in a manner tapering toward the heat sink 108.

FIG. 7 schematically shows an electronic component 700 in accordance with a seventh embodiment in a cross-sectional view. The electronic component 700 in accordance with the seventh embodiment comprises similarities with the electronic component 100 in accordance with the first embodiment. Similar or identical elements are provided with the same reference signs for this reason. Only differences with respect to the electronic component 100 in accordance with the first embodiment are explained in the following description.

In the case of the electronic component 700 in accordance with the seventh embodiment, the heat sink 108 is arranged by its underside 117 on a top side 701 of a ceramic substrate 702; to put it more precisely, the heat-conducting segments 115 of the segmented heat sink 108 are arranged on the top side 701 of the ceramic substrate 702 and, in contrast to the electronic component 100 in accordance with the first embodiment, are not embedded into a carrier substrate 105. In contrast to the illustration in FIG. 7, additionally in accordance with FIG. 5 the electronic semiconductor chip 101 may be segmented into chip segments 501 or the substrate 102 of the electronic semiconductor chip 101 may be segmented into substrate segments 503, but that is not absolutely necessary.

The ceramic substrate 702 comprises aluminum oxide by way of example. However, the ceramic substrate 702 may also comprise a different ceramic. The heat-conducting segments 115 comprise copper by way of example. However, the heat-conducting segments 115 may also comprise some other thermally conductive material, for example aluminum. The heat sink 108 and the ceramic substrate 702 form a DBC (direct bonded copper) carrier, on which the electronic semiconductor chip 101 is arranged. The heat-conducting segments 115 may be produced for example by etching a continuous layer, for instance composed of copper, arranged on the top side 701 of the ceramic substrate 702.

A DBC carrier typically comprises the ceramic substrate 702 and two heat sinks 108, 703 arranged respectively at the top side 701 and an underside 704 of the ceramic substrate 702. To put it another way, the ceramic substrate 702 is arranged by its underside 704, located opposite the top side, on the further heat sink 703. The further heat sink 703 likewise comprises copper by way of example. However, the further heat sink 703 may also comprise some other thermally conductive material, for example aluminum.

By way of example, the further heat sink 703 is segmented laterally into further heat-conducting segments 705. Adjacent further heat-conducting segments 705 are spaced apart in a plane parallel to the top side 701 of the further heat sink 703 by way of third trenches 706. The third trenches 706 extend from an underside 707 of the further heat sink 703 as far as the top side 701 of the further heat sink 703. By way of example, the heat-conducting segments 115 and the further heat-conducting segments 705 are arranged one over another in such a way that their center axes are arranged coaxially, although that is not necessary. However, the coaxial arrangement makes it possible to compensate for thermomechanical stresses on mutually opposite sides of the ceramic substrate 702. However, the further heat sink 703 need not necessarily be formed in a segmented manner. Instead, the further heat sink 703 may be constituted by a continuous layer.

FIG. 8 schematically shows an electronic component 800 in accordance with an eighth embodiment in a cross-sectional view. The electronic component 800 in accordance with the eighth embodiment comprises similarities with the electronic component 700 in accordance with the seventh embodiment. Similar or identical elements are provided with the same reference signs for this reason. Only differences with respect to the electronic component 700 in accordance with the seventh embodiment are explained in the following description.

In contrast to all the previously explained embodiments of the electronic component 100, 200, 300, 400, 500, 600, 700, the electronic component 800 in accordance with the eighth embodiment comprises a thinner electronic semiconductor chip 101. A thermal resistance of the electronic semiconductor chip 101 may be reduced as a result. The electronic semiconductor chip 101 of the eighth electronic component 800 comprises by way of example a thickness that is less than 100 μm, in particular less than 50 μm. However, the thickness of the electronic semiconductor chip 101 is not restricted to the specified value ranges. The electronic semiconductor chip 101 of all the other embodiments of the electronic component 100, 200, 300, 400, 500, 600, 700 may each comprise a thickness of up to 700 μm, where this value specification, too, is merely by way of example.

A method for producing an electronic component 100, 200, 300, 400, 500, 600, 700, 800 is explained in the following description.

In the context of a first method step of the method, the electronic semiconductor chip 101 is provided. In a second method step, a heat sink 108 provided for dissipating heat generated during the operation of the electronic semiconductor chip 101 is provided. In this case, the heat sink 108 and/or the electronic semiconductor chip 101 are/is provided in a segmented manner, that is to say that the heat sink 108 is provided in a manner segmented laterally into heat-conducting segments 115 and/or the electronic semiconductor chip 101 is provided in a manner segmented laterally into chip segments 501 at least in a region adjoining its underside 109. Adjacent heat-conducting segments 115 are spaced apart in a plane parallel to the top side 110 of the heat sink 108 by way of first trenches 116 extending from the underside 117 of the heat sink 108 as far as the top side 110 of the heat sink 108 and/or wherein adjacent chip segments 501 are spaced apart in a plane parallel to the underside 109 of the electronic semiconductor chip 101 by way of second trenches 502.

If the electronic semiconductor chip 101 comprises a substrate 102, the substrate 102 is segmented laterally into substrate segments 503 constituting the chip segments 501 at least in a region adjoining its underside 102. Adjacent substrate segments 503 are spaced apart in a plane parallel to the underside 109 of the electronic semiconductor chip 101 by way of the second trenches 502 and the substrate segments 503 are connected to one another via a membrane 505 formed at a top side 504 of the substrate 102 and in the region of the second trenches 502.

In a third method step, the electronic semiconductor chip 101 is arranged on the heat sink 108, wherein the electronic semiconductor chip 101 is secured by its underside 109 on the top side 110 of the heat sink 108 and is thermally connected to the heat sink 108. In the case where the electronic semiconductor chip 101 comprises a substrate 102, the substrate 102 is secured by its underside 111 on the top side 110 of the heat sink 108 and is thermally connected to the heat sink 018.

As already explained, the electronic semiconductor chip 101 may be provided in a segmented manner by virtue of the second trenches 502 being produced by way of photolithography, for example, in order to produce the chip segments 501 or the substrate segments 503. The way in which the heat sink 108 may be segmented is explained in the following description. FIG. 9 schematically shows method steps of a first exemplary embodiment 900 of a method for producing the heat-conducting segments 115 of the heat sink 108. In this case, the heat-conducting segments 115 are embedded into the elastic mold material 201.

In a first method step 901, a tool 906 is provided. The tool 906 comprises cupped indentations 907 for receiving bodies. In a second method step 902, thermally conductive bodies 908 are arranged in the cupped indentations 907 of the tool 906. Merely by way of example, the thermally conductive bodies 908 are formed in the shape of spheres. The spheres may be arranged in the cupped indentations 907 by being added to the tool 906 and distributed thereon. The thermally conductive and spherical bodies may comprise a diameter of 400 μm, for example. This is not absolutely necessary, however. The spheres may also comprise some other expedient diameter. The thermally conductive bodies 908 may also be formed as parallelepipeds, for example. The thermally conductive bodies 908 comprise copper by way of example, although they may also comprise some other thermally conductive material.

In a third method step 903, the elastic mold material 201 is arranged on the tool 906 in such a way that the thermally conductive bodies 908 are partly embedded into the elastic mold material 201. The elastic mold material 201 may be arranged on the tool 906 by way of a metering method, for example. After a process of curing the elastic mold material 201, in a fourth method step 904, the thermally conductive bodies 908 are firstly ground at sides facing away from the tool 906. The tool 906 is removed and, in a fifth method step 905, the thermally conductive bodies 908 are ground again, in such a way that the thermally conductive bodies 908 are ground so as to be planar on mutually opposite sides.

After the fifth method step 905, the heat-conducting segments 115 of the heat sink 108 are produced and may be used for an electronic component 200, 300, 400, 500, 600 in which the heat-conducting segments 115 are embedded into the elastic mold material 201. Optionally, the heat-conducting segments 115 may be coated, for example with a so-called ENEPIG (electroless nickel electroless palladium immersion gold) coating. In this case, an outer coating consists of gold, whereby oxidation of the thermally conductive bodies may be prevented.

FIG. 10 schematically shows method steps of a second exemplary embodiment 1000 of a method for producing the heat-conducting segments 115 of the heat sink 108. In this case, the heat-conducting segments 115 are likewise embedded into the elastic mold material 201.

In a first method step 1001, a further tool 1006 is provided. The further tool 1006 comprises through openings 1007 for receiving bodies. In a second method step 901, thermally conductive bodies 908 are arranged in the through openings 1007 of the further tool 1006. Once again, the thermally conductive bodies 908 are formed in the shape of spheres merely by way of example.

In a third method step 1003, the thermally conductive bodies 906 are pressed, with the result that the thermally conductive bodies are formed in planar fashion on mutually opposite sides. The heat-conducting segments 115 are produced as a result. In a fourth method step 1004, the pressed thermally conductive bodies 906 are arranged on a temporary carrier 1008. The temporary carrier 1008 may also already serve as a carrier in each case during the first to third method steps 1001, 1002, 1003. The elastic mold material 201 is arranged on the temporary carrier 1008 and the heat-conducting segments 115 are embedded into the elastic mold material 201. In a fifth method step 1005, the temporary carrier 1008 is removed. In order to be able to remove the temporary carrier 1008 more easily, it may comprise a PDMS coating (polydimethylsiloxane) at its side facing the heat-conducting segments 115, for example. Optionally, the heat-conducting segments 115 may be coated, for example with an ENEPIG coating.

Embedding the heat-conducting segments 115 into the elastic mold material 201 is not necessarily required. Instead, the heat-conducting segments 115 may also be embedded into the carrier substrate 105. For this purpose, after the step of pressing, the heat-conducting segments 115 are embedded into an epoxy resin, for example, by way of film-assisted transfer molding. If the heat-conducting segments 115 in accordance with FIG. 9 and FIG. 10 are embedded into the elastic mold material 201, the elastic mold material 201 in the form of the elastic mat may be arranged into a cutout 202 of a carrier substrate 105.

FIG. 11 schematically shows method steps of a third exemplary embodiment 1100 for producing the heat-conducting segments 115 of the heat sink 108. In this case, the heat-conducting segments 115 are likewise embedded into the elastic mold material 201, but that is not absolutely necessary. Instead of the elastic mold material 201, the heat-conducting segments 115 may also be embedded into a carrier substrate 105, comprising an epoxy resin, for example.

In a first method step 1101, a leadframe 1104 is provided. The leadframe 1104 comprises copper by way of example. However, the leadframe 1104 may also comprise some other thermally conductive material. The leadframe 1004 comprises a top side 1105 and an underside 1106 located opposite the top side 1105. At its underside 1106, the leadframe 1104 is structured in such a way that it comprises projections 1107.

In a second method step 1102, the leadframe 1104 is embedded into the elastic mold material 201, in such a way that only the projections 1107 are embedded into the elastic mold material 201.

In a third method step 1103, the leadframe 1104 is etched at its top side 1105, in regions between the projections 1107 and as far as the elastic mold material 201. For example, photolithographic methods may be used in this case. After the etching of the leadframe 1104, the projections 1107 are completely separated from one another and constitute the heat-conducting segments 115. The latter may likewise be coated, for instance with the ENEPIG coating.

FIG. 12 schematically shows the steps of a method 1200 for producing the electronic component 400 in accordance with the fourth embodiment.

In a first step 1201, the carrier substrate 105 with the electrical contacts 106 embedded therein and with the frame 301 arranged on the carrier substrate 105 is provided. The carrier substrate 105 is arranged on the adhesive tape 203. In a second step 1202, the heat-conducting segments 115 are arranged in the cavity 303 and in the cutout 202 of the carrier substrate 105. The heat-conducting segments 115 produced by pressing thermally conductive bodies may be used for this purpose. In this case, the heat-conducting segments 115 produced by pressing, in the context of their production, are not embedded into the elastic mold material 201, but rather are used directly after the pressing step. In order to arrange the heat-conducting segments 115 in the cavity 303, they may be transferred using a suction tool, for example.

In a third step 1203, the electronic semiconductor chip 101 is arranged in the cavity 303 and on the heat-conducting segments 115. Alternatively, it is possible for the heat-conducting segments 115, before being arranged in the cavity 303, firstly to be secured to the underside 109 of the electronic semiconductor chip 101. For example, the heat-conducting segments 115 may be soldered to the electronic semiconductor chip 101 separately.

In a fourth step 1204, the dam 306 is arranged on the electronic semiconductor chip 101 and the electronic semiconductor chip 101 is connected to the electrical contacts 106. In a fifth step 1205, the further mold material 304 is arranged in the cavity 303. The adhesive tape 203 may be removed after a process of curing the further mold material 304.

Each of the electronic components 100, 200, 300, 400, 500, 600, 700, 800 may be produced in such a way that in each case a plurality of electronic components 100, 200, 300, 400, 500, 600, 700, 800 are produced simultaneously. Referring by way of example to the electronic component 400 in accordance with the fourth embodiment and FIG. 12, a plurality of carrier substrates 105 each with a frame 301 are arranged next to one another in a matrix-type manner and are simultaneously each equipped with a heat sink 108 and an electronic semiconductor chip 101 and the respective cavities are filled with the further mold material 304.

The invention has been illustrated and described in greater detail on the basis of the preferred exemplary embodiments. Nevertheless, the invention is not restricted to the examples disclosed. Rather, other variations may be derived therefrom by a person skilled in the art, without departing from the scope of protection of the invention.

### LIST OF REFERENCE SIGNS

100 first electronic component
101 electronic semiconductor chip
102 substrate
103 electronic semiconductor arrangement
104 conversion layer
105 carrier substrate
106 electrical contacts
107 bond wire
108 heat sink
109 underside of the electronic semiconductor chip
110 top side of the heat sink
111 underside of the substrate
112 solder material
113 connecting surface between electronic semiconductor chip and heat sink
114 connecting surface segments
115 heat-conducting segments
116 first trenches
117 underside of the heat sink
200 second electronic component
201 elastic mold material
202 cutout in the carrier substrate
203 adhesive tape
204 underside of the carrier substrate
205 underside of the elastic material
300 third electronic component
301 frame
302 top side of the carrier substrate
303 cavity
304 further mold material
305 top side of the electronic semiconductor chip
306 dam
307 top side of the substrate
308 potting surface of the further mold material
400 fourth electronic component
500 fifth electronic component
501 chip segments
502 second trenches
503 substrate segments
504 top side of the substrate
505 membrane
600 sixth electronic component
700 seventh electronic component
701 top side of the ceramic substrate
702 ceramic substrate
703 further heat sink
704 underside of the ceramic substrate
705 further heat-conducting segments
706 third trenches
707 underside of the further heat sink
708 top side of the heat sink
800 eighth electronic component
900 first exemplary embodiment of a method for producing the heat-conducting segments of the heat sink
901 first method step
902 second method step
903 third method step
904 fourth method step
905 fifth method step
906 tool
907 cupped indentations of the tool
908 thermally conductive bodies
1000 second exemplary embodiment of a method for producing the heat-conducting segments of the heat sink
1001 first method step
1002 second method step
1003 third method step
1004 fourth method step
1005 fifth method step
1006 further tool
1007 through openings in the further tool
1008 temporary carrier
1100 third exemplary embodiment of a method for producing the heat-conducting segments of the heat sink
1101 first method step
1102 second method step
1103 third method step
1104 leadframe
1105 top side of the leadframe
1106 underside of the leadframe
1107 projections of the leadframe

1. An electronic component comprising an electronic semiconductor chip and a heat sink provided for dissipating heat generated during the operation of the electronic semiconductor chip,
wherein the electronic semiconductor chip is secured by an underside on a top side of the heat sink and is thermally connected to the heat sink,
wherein a connecting surface formed between the underside of the electronic semiconductor chip and the top side of the heat sink is segmented into connecting surface segments,
wherein adjacent connecting surface segments are formed spaced apart from one another in a plane parallel to the underside of the electronic semiconductor chip,
wherein the heat sink is segmented laterally into heat-conducting segments,
wherein adjacent heat-conducting segments are spaced apart in a plane parallel to the top side of the heat sink by way of first trenches,
wherein the first trenches extend from an underside of the heat sink as far as the top side of the heat sink,
wherein the heat-conducting segments are embedded into an elastic mold material, wherein in the electronic semiconductor chip is segmented laterally into chip segments at least in a region adjoining its underside,
wherein adjacent segments are spaced apart in a plane parallel to the underside of the electronic semiconductor by way of second trenches.

2. (canceled)

3. The electronic component according to claim 1,
wherein the electronic semiconductor chip comprises a substrate,
wherein the substrate is secured by an underside on the top side of the heat sink and is thermally connected to the heat sink,
wherein the substrate is segmented laterally into substrate segments constituting the chip segments at least in a region adjoining its underside,
wherein adjacent substrate segments are spaced apart in a plane parallel to the underside of the electronic semiconductor chip by way of the second trenches,
wherein the substrate segments are connected to one another via a membrane formed at a top side of the substrate and in the region of the second trenches.

4. The electronic component according to claim 2,
wherein the substrate segments are formed in a manner tapering toward the heat sink.

5. The electronic component according to any one of the preceding claim 1,
wherein an aspect ratio between a thickness of the heat-conducting segments and a lateral extent of the heat-conducting segments is less than one.

6. A method for producing an electronic component comprising the following method steps:
providing an electronic semiconductor chip,
providing a heat sink provided for dissipating heat generated during the operation of the electronic semiconductor chip,
wherein the heat sink and the electronic semiconductor chip are provided in a segmented manner,
wherein the heat sink is provided in a manner segmented laterally into heat-conducting segments and the electronic semiconductor chip is provided in a manner segmented laterally into chip segments at least in a region adjoining an underside of the electronic semiconductor chip,
wherein adjacent heat-conducting segments are spaced apart in a plane parallel to a top side of the heat sink by way of first trenches extending from an underside of the heat sink as far as the top side of the heat sink and wherein adjacent chip segments are spaced apart in a plane parallel to the underside of the electronic semiconductor chip by way of second trenches,
arranging the electronic semiconductor chip on the heat sink, wherein the electronic semiconductor chip is secured by its underside on the top side of the heat sink and is thermally connected to the heat sink,
wherein the heat-conducting segments are embedded into an elastic mold material.

7. The method according to claim 5
wherein providing the heat sink comprises the following method steps:
providing thermally conductive bodies,
producing the heat-conducting segments of the heat sink by grinding or pressing the thermally conductive bodies.

8. The method according to claim 6,
wherein the electronic semiconductor chip comprises a substrate,
wherein the substrate is secured by an underside on the top side of the heat sink and is thermally connected to the heat sink,
wherein the substrate is segmented laterally into substrate segments constituting the chip segments at least in a region adjoining its underside, in such a way that the substrate segments are spaced apart in a plane parallel to the underside of the electronic semiconductor chip by way of the second trenches and the substrate segments are connected to one another via a membrane formed at a top side of the substrate and in the region of the second trenches.
